(19) United States
(12) Patent Application Publication
(10) Pub. No.: US 2026/0164891 A1
(43) Pub. Date: Jun. 11, 2026

(54) DISPLAY PANEL AND ELECTRONIC APPARATUS INCLUDING THE SAME

(71) Applicant: Samsung Display Co., Ltd., Yongin-si (KR)

(72) Inventors: Youngsoo No, Yongin-si (KR); Mingwan Kim, Yongin-si (KR); Yeongho Kim, Yongin-si (KR); Seonbeom Ji, Yongin-si (KR)

(21) Appl. No.: 19/415,152

(22) Filed: Dec. 10, 2025

(30) Foreign Application Priority Data
Dec. 10, 2024 (KR) 10-2024-0183110

(51) Int. Cl. H10H 29/49; H10W 46/00

(52) U.S. Cl. CPC H10H 29/49; H10W 46/301

(57) ABSTRACT

A display panel includes: a substrate including a display area and a peripheral area outside the display area; a plurality of display elements on the substrate in the display area; a display driving chip on the substrate in the peripheral area; and a display circuit board on the display driving chip, wherein the display circuit board includes: a first opening defined in a lower surface of the display circuit board to accommodate the display driving chip; and a bridge on the first opening and partially covering an upper surface of the display driving chip.

### CROSS-REFERENCE TO RELATED APPLICATION

The present application claims priority to and the benefit of Korean Patent Application No. 10-2024-0183110, filed on Dec. 10, 2024, in the Korean Intellectual Property Office, the entire disclosure of which is incorporated herein by reference.

### BACKGROUND

### 1. Field

Aspects of some embodiments relate to a display panel and an electronic apparatus including the display panel.

### 2. Description of the Related Art

Display panels may provide visual information such as images to users. The display panels may include a substrate divided into a display area and a peripheral area. A scan line is insulated from a data line in the display area, and a plurality of pixels may be arranged in the display area. In addition, a thin-film transistor and a pixel electrode electrically connected to the thin-film transistor may be provided in the display area, wherein each of the thin-film transistor and the pixel electrode corresponds to each of the pixels. In addition, an opposite electrode may be provided in the display area, wherein the opposite electrode is commonly provided to the pixels. Various wirings, a scan driver, a data driver, a controller, a pad portion and the like, which transfer electrical signals to the display area, may be provided in the peripheral area.

The display panel may include an integrated circuit chip located on a substrate of the display panel to transfer electrical signals. In addition, the display panel may include a printed circuit board connected to one side of the substrate of the display panel. The substrate of the display panel may be provided as a flexible substrate, and a portion of the substrate may be bent. Because the substrate is bent, a printed circuit board connected to one side of the substrate may be located under the backside of the substrate. In the present disclosure, the integrated circuit chip is denoted by a ‘display driving chip’, and the printed circuit board is denoted by a ‘display circuit board’.

The above information disclosed in this Background section is only for enhancement of understanding of the background and therefore the information discussed in this Background section does not necessarily constitute prior art.

### SUMMARY

Aspects of some embodiments relate to a display panel and an electronic apparatus including the display panel. The display panel may include a light-emitting diode as a light-emitting element.

When connecting a display circuit board to one side of a substrate, the edge of the substrate and the edge of the display circuit board may be connected by pressing the edges to each other. In this case, due to the size (e.g., length) of the display circuit board, a portion of the display circuit board may sag.

To solve this sagging of the display circuit board, when the display circuit board is connected to the substrate by overlapping a portion of the substrate, the display circuit board may cover a portion of the display driving chip provided to the substrate, and it may be difficult to control heat occurring in the display driving chip.

To solve the heat control issue of the display driver chip, when the display circuit board is open in a region overlapping the display driver chip, a space to place electronic components (e.g., wiring) provided on the display circuit board may be insufficient.

Aspects of some embodiments include a display panel and an electronic apparatus including the display panel.

Additional aspects will be set forth in part in the description which follows and, in part, will be apparent from the description, or may be learned by practice of the presented embodiments of the disclosure.

According to one or more embodiments, a display panel includes a substrate including a display area and a peripheral area outside the display area, a plurality of display elements on the substrate in the display area, a display driving chip on the substrate in the peripheral area, and a display circuit board on the display driving chip, wherein the display circuit board includes a first opening defined in a lower surface of the display circuit board to accommodate the display driving chip, and a bridge on the first opening and partially covering an upper surface of the display driving chip.

According to some embodiments, the display circuit board may include a second opening connected to the first opening and open to an upper surface of the display circuit board.

According to some embodiments, the display circuit board may include a plurality of second openings and a plurality of bridges, and the plurality of second openings and the plurality of bridges may be alternately arranged in one direction.

According to some embodiments, the display circuit board may include a plurality of wirings on the bridge.

According to some embodiments, the display panel may further include a plurality of pads on the substrate, and an alignment mark adjacent to an outermost pad among the plurality of pads, wherein the display circuit board may include an alignment opening overlapping the alignment mark.

According to some embodiments, the display panel may further include an adhesive layer between the substrate and the display circuit board, wherein the adhesive layer may include an opening overlapping the display driving chip.

According to some embodiments, the substrate may be bent in the peripheral area, and the display driving chip and the display circuit board may be located below one surface of the substrate.

According to one or more embodiments, an electronic apparatus includes a display panel and a housing accommodating the display panel, wherein the display panel includes a substrate including a display area and a peripheral area outside the display area, a plurality of display elements on the substrate in the display area, a display driving chip on the substrate in the peripheral area, and a display circuit board on the display driving chip, wherein the display circuit board includes a plurality of first openings overlapping the display driving chip and defined across an entire thickness direction of the display circuit board, and a plurality of second openings overlapping the display driving chip and defined across a portion of the thickness direction of the display circuit board, and wherein the plurality of first openings and the plurality of second openings are alternately arranged in one direction.

According to some embodiments, the plurality of first openings and the plurality of second openings may be connected to each other.

According to some embodiments, the plurality of second openings may be open to a lower surface of the display circuit board.

According to some embodiments, the plurality of first openings and the plurality of second openings may be configured to accommodate the display driving chip.

According to some embodiments, the display circuit board may include a plurality of wirings at least partially overlapping the plurality of second openings.

According to some embodiments, the electronic apparatus may further include a plurality of pads on the substrate, and an alignment mark adjacent to an outermost pad among the plurality of pads, wherein the display circuit board may include an alignment opening overlapping the alignment mark.

According to some embodiments, the electronic apparatus may further include an adhesive layer between the substrate and the display circuit board, wherein the adhesive layer may include an opening overlapping the display driving chip.

According to some embodiments, the substrate may be bent in the peripheral area, and the display driving chip and the display circuit board may be located below one surface of the substrate.

According to one or more embodiments, an electronic apparatus includes a display panel and a housing accommodating the display panel, wherein the display panel includes a substrate including a display area and a peripheral area outside the display area, a plurality of display elements on the substrate in the display area, a display driving chip on the substrate in the peripheral area, and a display circuit board on the display driving chip, wherein the display circuit board includes a first opening defined in a lower surface of the display circuit board to accommodate the display driving chip, and a bridge on the first opening and partially covering an upper surface of the display driving chip.

According to some embodiments, the display circuit board may include a second opening connected to the first opening and open to an upper surface of the display circuit board.

According to some embodiments, the display circuit board may include a plurality of second openings and a plurality of bridges, and the plurality of second openings and the plurality of bridges may be alternately arranged in one direction.

According to some embodiments, the display circuit board may include a plurality of wirings on the bridge.

### BRIEF DESCRIPTION OF THE DRAWINGS

The above and other aspects, features, and characteristics of certain embodiments of the present disclosure will be more apparent from the following description taken in conjunction with the accompanying drawings, in which:

FIG. 1 is a schematic plan view of an electronic apparatus according to some embodiments;

FIG. 2 is a schematic plan view of a display panel according to some embodiments;

FIG. 3 is an enlarged plan view of a display panel according to some embodiments;

FIG. 4 is an exploded perspective view of a display panel and a perspective view of a lower surface of a portion of a display panel according to some embodiments;

FIG. 5 is a plan view of a display circuit board according to some embodiments;

FIG. 6 is a cross-sectional view of a display circuit board according to some embodiments;

FIG. 7 is a cross-sectional view of a display circuit board according to some embodiments;

FIG. 8 is a plan view of a display circuit board according to some embodiments;

FIG. 9 is a cross-sectional view of a display circuit board according to some embodiments;

FIG. 10 is a cross-sectional view of a display circuit board according to some embodiments;

FIG. 11A is a cross-sectional view of a display panel according to some embodiments;

FIG. 11B is a cross-sectional view of a display panel according to some embodiments;

FIG. 12 is a cross-sectional view of a display panel according to some embodiments;

FIG. 13 is a schematic circuit diagram of a pixel according to some embodiments; and

FIG. 14 is a cross-sectional view of a display panel according to some embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b, and c” indicates only a, only b, only c, both a and b, both a and c, both b and c, all of a, b, and c, or variations thereof.

As the disclosure allows for various changes and numerous embodiments, certain embodiments will be illustrated in the drawings and described in the written description. Effects and features of the disclosure, and methods for achieving them will be clarified with reference to embodiments described below with reference to the drawings. However, the disclosure is not limited to embodiments described below and may be implemented in various forms.

Hereinafter, embodiments will be described with reference to the accompanying drawings, wherein like reference numerals refer to like elements throughout and a repeated description thereof is omitted.

While such terms as “first” and “second” may be used to describe various elements, such elements must not be limited to the above terms. The above terms are used to distinguish one element from another.

The singular forms “a,” “an,” and “the” as used herein are intended to include the plural forms as well unless the context clearly indicates otherwise.

It will be understood that the terms “comprise,” “comprising,” “include” and/or “including” as used herein specify the presence of stated features or elements but do not preclude the addition of one or more other features or elements.

It will be further understood that, when a layer, region, or element is referred to as being “on” another layer, region, or element, it can be directly or indirectly on the other layer, region, or element. That is, for example, intervening layers, regions, or elements may be present.

Sizes of elements in the drawings may be exaggerated or reduced for convenience of explanation. As an example, the size and thickness of each element shown in the drawings are arbitrarily represented for convenience of description, and thus, the disclosure is not necessarily limited thereto.

In embodiments below, x axis, y axis and z axis are not limited to three axes of the rectangular coordinate system, and may be interpreted in a broader sense. For example, x axis, y axis, and z axis may be perpendicular to one another, or may represent different orientations that are not perpendicular to one another.

In the case where a certain embodiment may be implemented differently, a specific process order may be performed in the order different from the described order. As an example, two processes successively described may be simultaneously performed substantially and performed in the opposite order.

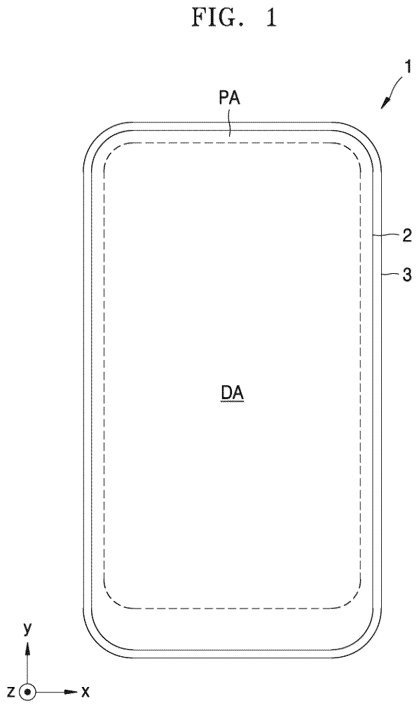

FIG. 1 is a schematic plan view of an electronic apparatus 1 according to some embodiments.

The electronic apparatus 1 may include a display panel 2 and a housing 3. According to some embodiments, the display panel 2 may be accommodated in the housing 3.

The electronic apparatus 1 may include various products including televisions, notebook computers, monitors, advertisement boards, Internet of things (IoTs) apparatuses as well as portable electronic apparatuses including mobile phones, smartphones, tablet personal computers (PCs), mobile communication terminals, electronic organizers, electronic books, portable multimedia players (PMPs), navigation apparatuses, and ultra mobile personal computers (UMPCs). In addition, the electronic apparatus 1 according to some embodiments may include wearable devices including smartwatches, watchphones, glasses-type displays, and head-mounted displays (HMDs). In addition, according to some embodiments, electronic apparatus 1 may include a display screen in instrument panels for automobiles, center fascias for automobiles, or center information displays (CIDs) arranged on a dashboard, mirror displays that replace side mirrors of automobiles, and displays of an entertainment system arranged on the backside of front seats for backseat passengers in automobiles. The display panel 2 may be included in the electronic apparatus 1 as an element for displaying moving images or still images in various embodiments of the electronic apparatuses 1. Although it is shown in FIG. 1 that the electronic apparatus 1 is a smartphone, the disclosure is not limited thereto.

The display panel 2 may include a display area DA and a peripheral area PA outside the display area DA.

The display area DA is a region in which images are displayed, and a plurality of pixels may be located in the display area DA. The display area DA may have various shapes, for example, circular shapes, elliptical shapes, polygonal shapes, or shapes of specific figures. It is shown as an example in FIG. 1 that the display area DA has an approximately rectangular shape having round corners.

The peripheral area PA may be located outside the display area DA. The peripheral area PA may be arranged to surround (e.g., in a periphery or outside a footprint of) at least a portion of the display area DA.

Hereinafter, although an organic light-emitting display panel is described as an example of the display panel 2 according to some embodiments, the display panel according to the disclosure is not limited thereto. According to some embodiments, the display panel 2 according to the disclosure may be an inorganic light-emitting display panel or a quantum-dot light-emitting display panel. As an example, an emission layer of a display element provided to the display panel 2 may include an organic material, an inorganic material, quantum dots, an organic material and quantum dots, or an inorganic material and quantum dots.

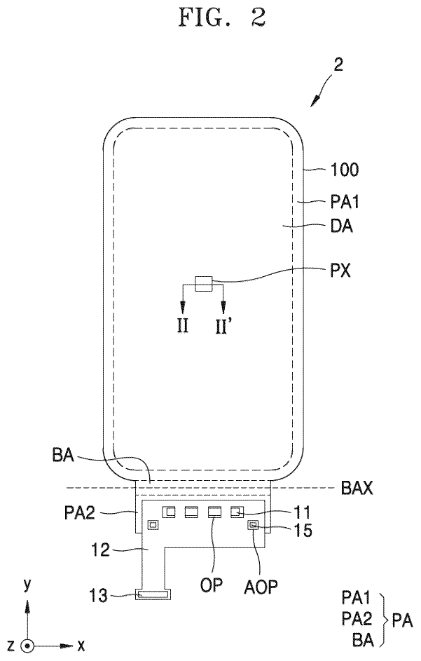

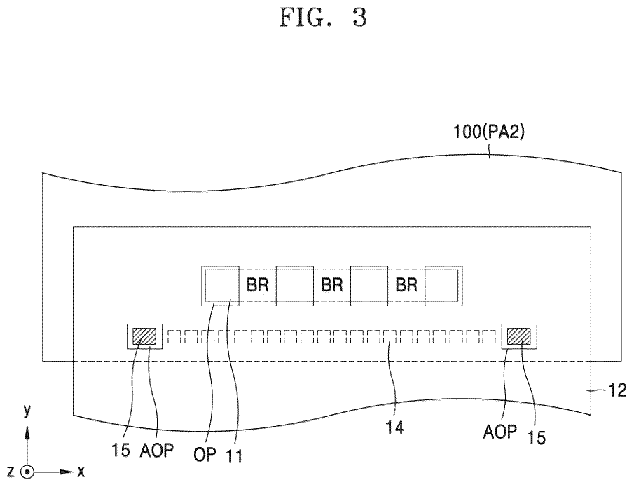

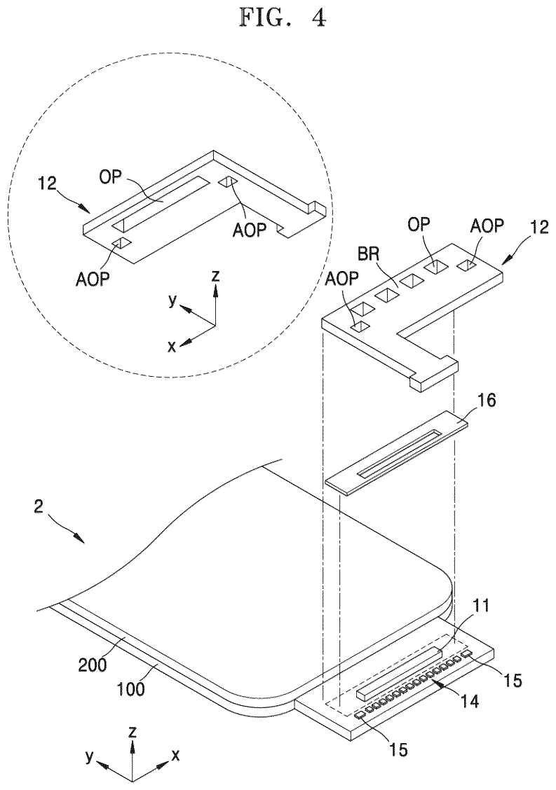

FIG. 2 is a schematic plan view of the display panel 2 according to some embodiments. FIG. 3 is an enlarged plan view of a portion of the display panel 2 according to some embodiments. FIG. 4 is an exploded perspective view of the display panel 2 and a perspective view of a lower surface of a portion of the display panel 2 according to some embodiments.

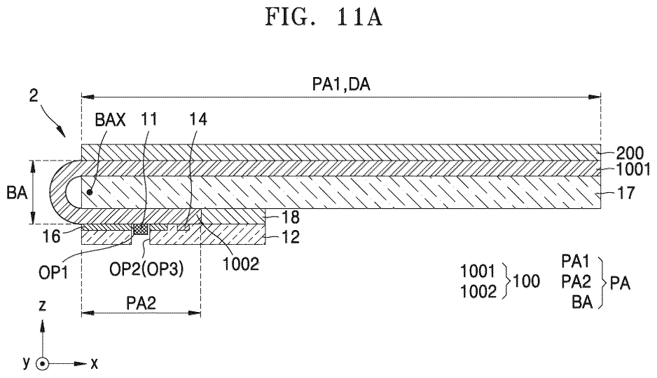

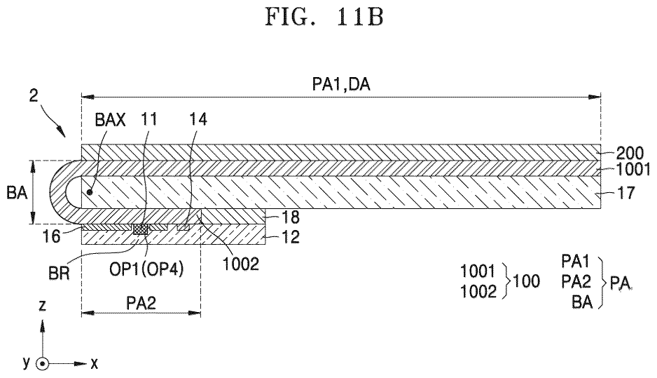

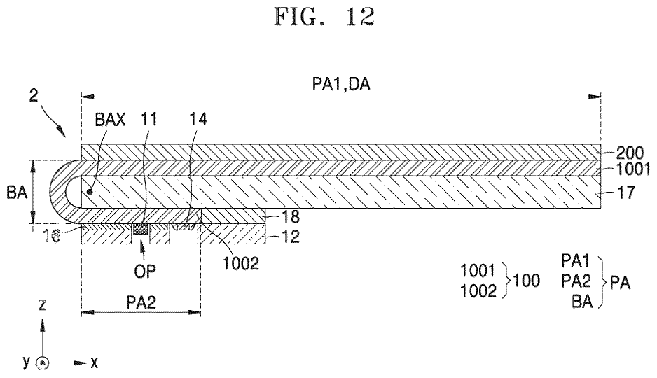

Although FIGS. 2 to 4 show the display panel 2 that is unfolded, this is for convenience of illustration and description. As described below with reference to FIGS. 11A, 11B, and 12, the display panel 2 may be bent such that a portion thereof is located below another portion thereof.

Referring to FIGS. 2 to 4, the display panel 2 may include a substrate 100, a display element layer 200, a display driving chip 11, a display circuit board 12, a sensor driving chip 13, a plurality of pads 14, an alignment mark 15, and an adhesive layer 16.

The display panel 2 may include pixels PX as display elements. The pixels PX may be located in the display area DA. The pixels PX may include a light-emitting diode and a pixel circuit (or thin-film transistor) connected to the light-emitting diode. Although FIG. 2 illustrates a single pixel PX, as a person having ordinary skill in the art would appreciate, the display panel 2 may include any suitable number of pixels PX according to the design and size of the display panel 2.

The display panel 2 may include the display area DA and the peripheral area PA. Because the display panel 2 includes the substrate 100, it may be understood that the substrate 100 includes the display area DA and the peripheral area PA. Alternatively, it may be understood that the display area DA and the peripheral area PA are defined in the substrate 100.

The peripheral area PA may include a first peripheral area PA1, a second peripheral area PA2, and a bent area BA. The first peripheral area PA1 may surround the display area DA entirely. The second peripheral area PA2 may be located outside the first peripheral area PA1. Because the plurality of pads 14 may be located in the second peripheral area PA2, the second peripheral area PA2 may be understood as a pad area. The bent area BA may be located between the first peripheral area PA1 and the second peripheral area PA2. The display panel 2 may be bent in the bent area BA. As an example, as described below with reference to FIGS. 11A, 11B, and 12, the display panel 2 (or substrate 100) may be bent around a bending axis BAX in the bent area BA.

The substrate 100 may include an insulating material such as glass, quartz, a polymer resin or the like. The substrate 100 may be a rigid substrate or a flexible substrate that is bendable, foldable, and rollable. In the present disclosure, a case where the substrate 100 is a flexible substrate is mainly described.

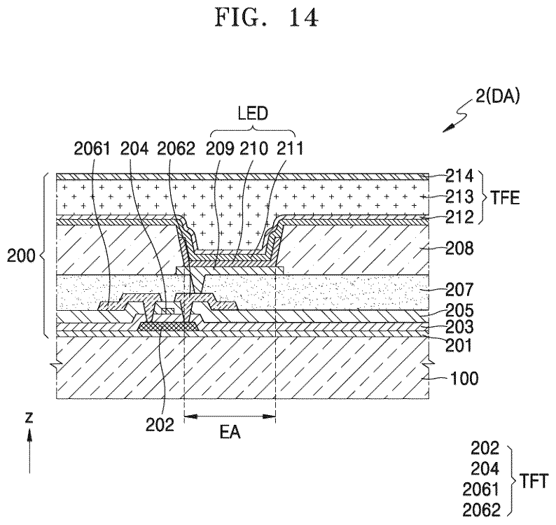

The display element layer 200 may be located on the substrate 100. The display element layer 200 may be a layer in which the pixels PX of the display panel 2 are located. The display element layer 200 may not be located in the bent area BA and the second peripheral area PA2. A specific structure of the display element layer 200 is described below with reference to FIG. 14.

The display driving chip 11 may be located on the substrate 100. The display driving chip 11 may be located in the peripheral area PA, for example, the second peripheral area PA2. The display driving chip 11 may receive control signals and power voltages, and generate and output signals and voltages for driving the pixels PX of the display element layer 200. The display driving chip 11 may include an integrated circuit. The display driving chip 11 may be at least partially covered by the display circuit board 12. The display driving chip 11 may be connected to the display element layer 200 and/or the plurality of pads 14 through wirings.

The plurality of pads 14 may be located on the substrate 100. The plurality of pads 14 may be located in the peripheral area PA, for example, the second peripheral area PA2. According to some embodiments, the plurality of pads 14 may be arranged in a −y direction with respect to the display driving chip 11. The plurality of pads 14 may be covered by the display circuit board 12 entirely. According to some embodiments, at least some of the plurality of pads 14 may be electrically connected to the display circuit board 12, for example, electronic elements provided to the display circuit board 12. According to some embodiments, at least some of the plurality of pads 14 may be electrically connected to the display element layer 200.

Although FIGS. 3 and 4 show a case where the plurality of pads 14 are aligned in a ±x direction, the disclosure is not necessarily limited thereto. The plurality of pads 14 may be provided in an arbitrary different direction or arrangement.

The alignment mark 15 may be located on the substrate 100. The alignment mark 15 may be located in the peripheral area PA, for example, the second peripheral area PA2. The alignment mark 15 may be located adjacent to the plurality of pads 14.

According to some embodiments, the alignment mark 15 may be located adjacent to an outermost pad(s) 14 among the plurality of pads 14. According to some embodiments, a single alignment mark 15 may be provided, or a plurality of alignment marks 15 may be provided. FIGS. 2 to 4 show embodiments in which one alignment mark 15 is arranged in a +x direction of an outermost pad in the +x direction among the plurality of pads 14, one alignment mark 15 is arranged in a −x direction of an outermost pad 14 in the −x direction among the plurality of pads 14, and thus, a total of two alignment marks 15 is provided. The disclosure is not limited to the number of alignment marks 15.

According to some embodiments, as shown in FIG. 4, the alignment mark 15 may take a form located on the upper surface of the substrate 100 and protruding (e.g., in a +z direction). According to some embodiments, the alignment mark 15 may take a form of a groove formed in the substrate 100. According to some embodiments, the alignment mark 15 may take a form of a groove formed on the substrate 100, filled with a material that may be distinguished from the substrate 100.

The alignment mark 15 may overlap an alignment opening AOP defined in the display circuit board 12. Accordingly, when the display circuit board 12 is located on the substrate 100, the alignment mark 15 may be located in the alignment opening AOP. Although FIGS. 2 and 3 show the alignment mark 15 and the alignment opening AOP have a rectangular shape, the disclosure is not necessarily limited thereto. The alignment mark 15 and the alignment opening AOP may take an arbitrary different form or forms different from each other.

The display circuit board 12 may be located on the substrate 100. As an example, the display circuit board 12 may be located on the display driving chip 11. A portion of the display circuit board 12 may overlap the peripheral area PA, for example, the second peripheral area PA2. Another portion of the display circuit board 12 may be located outside the substrate 100. In other words, the display circuit board 12 may partially overlap and be connected to the substrate 100 and may extend in one direction. As an example, the display circuit board 12 may overlap and be connected to the substrate 100 and may extend in a −y direction in the second peripheral area PA2.

The display circuit board 12 may be electrically connected to the display element layer 200. According to some embodiments, the display circuit board 12 may be electrically connected to the plurality of pads 14. According to some embodiments, the plurality of pads 14 may be electrically connected to the display element layer 200. Accordingly, the display circuit board 12 may be electrically connected to the display element layer 200 through the plurality of pads 14. According to some embodiments, the display circuit board 12 may be electrically connected to a separate main circuit board. The main circuit board may include, for example, a main processor including an integrated circuit, a camera apparatus, a wireless communication unit, an input unit, an output unit, an interface, a memory, and/or a power supply unit.

The display circuit board 12 may include a printed circuit board (PCB). According to some embodiments, the display circuit board 12 may include a flexible printed circuit board (FPCB) that is bendable. According to some embodiments, the display circuit board 12 may include a rigid printed circuit board (RPCB) that is rigid and is not easily bendable. According to some embodiments, the display circuit board 12 may include a composite printed circuit board including both an FPCB and an RPCB.

An opening OP overlapping the display driving chip 11 may be defined in the display circuit board 12. In the present disclosure, in describing the opening OP of the display circuit board 12, the upper surface of the display circuit board 12 may denote a surface facing away from the substrate 100, for example, a surface facing the +z direction in FIG. 4, and a surface facing a −z direction in FIG. 11A. Similarly, the lower surface of the display circuit board 12 may denote a surface facing the substrate 100, for example, a surface facing the −z direction in FIG. 4 and a surface facing the +z direction in FIG. 11A.

The opening OP of the display circuit board 12 may be open to the lower surface of the display circuit board 12. A shape of a portion of the opening OP of the display circuit board 12 open to the lower surface of the display circuit board 12 may be entirely similar to the display driving chip 11. Accordingly, when arranging the display circuit board 12 on the substrate 100 to cover the display driving chip 11, at least a portion of the display driving chip 11 may be accommodated in the opening OP of the display circuit board 12.

The opening OP of the display circuit board 12 may be open to the upper surface of the display circuit board 12. A portion of the opening OP of the display circuit board 12 open to the upper surface of the display circuit board 12 may be partially overlap the display driving chip 11. As an example, referring to FIG. 3, a portion of the opening OP open to the upper surface of the display circuit board 12 may have a form of a plurality of holes apart from each other and expose a portion of the display driving chip 11. A portion of the display circuit board 12 may be located between the plurality of holes, and this portion of the display circuit board 12 is denoted by a bridge BR in the present disclosure. According to some embodiments, the display circuit board 12 may include a plurality of bridges BR. According to some embodiments, the plurality of bridges BR and the plurality of holes may be alternately arranged in one direction (e.g., ±x direction). The bridge BR may partially cover the display driving chip 11. Although FIGS. 3 and 4 show a total of three bridges BR, the disclosure is not necessarily limited to this number.

The alignment opening AOP overlapping the alignment mark 15 may be defined in the display circuit board 12. The number of alignment openings AOP may be the same as the number of alignment marks 15. The substrate 100 and the display circuit board 12 may be aligned to each other by aligning the alignment mark 15 to the alignment opening AOP. The alignment opening AOP may be defined by passing through the display circuit board 12 in a thickness direction (e.g., ±z direction). Accordingly, in a plan view, the alignment mark 15 may be viewed through the alignment opening AOP.

The sensor driving chip 13 may be located on the display circuit board 12. The sensor driving chip 13 may include an integrated circuit. The sensor driving chip 13 may be attached on the display circuit board 12 and connected to other electronic elements provided to the display circuit board 12. In addition to the sensor driving chip 13, various electronic elements may be additionally located on the display circuit board 12.

The adhesive layer 16 may be located between the substrate 100 and the display circuit board 12. The display circuit board 12 may be attached to the substrate 100 through the adhesive layer 16. A portion of the adhesive layer 16 may be open not to cover the display driving chip 11. As an example, the adhesive layer 16 may include an opening overlapping the display driving chip 11. In other words, in a plan view, the adhesive layer 16 may surround the display driving chip 11 entirely.

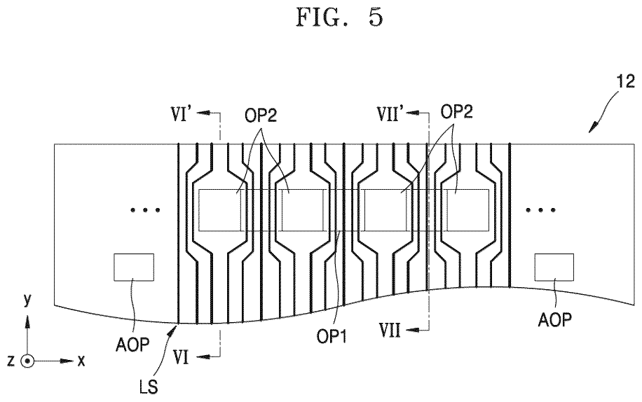

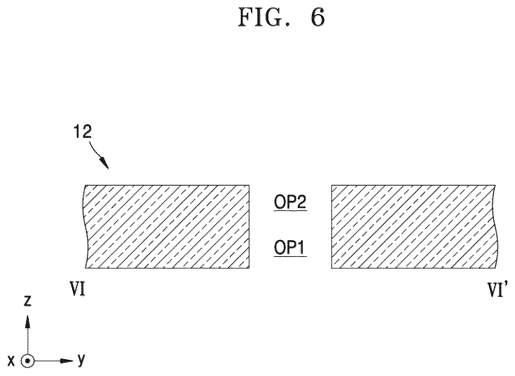

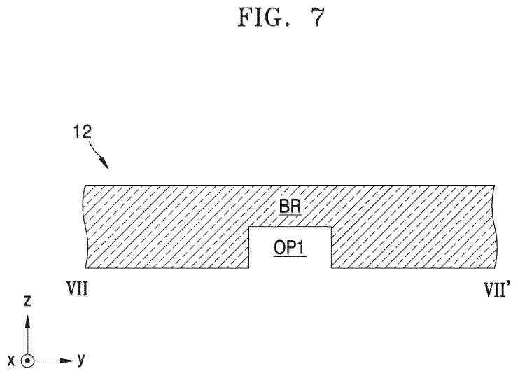

FIG. 5 is a plan view of a portion of the display circuit board 12 according to some embodiments. FIG. 6 is a cross-sectional view of a portion of the display circuit board 12 according to some embodiments. FIG. 7 is a cross-sectional view of a portion of the display circuit board 12 according to some embodiments.

FIG. 6 is a cross-sectional view of the display circuit board 12, taken along line VI-VI′ of FIG. 5. FIG. 7 is a cross-sectional view of the display circuit board 12, taken along line VII-VII′ of FIG. 5.

Referring to FIGS. 4 to 7 together, the opening OP of the display circuit board 12 may include a first opening OP1 and a second opening OP2.

The first opening OP1 of the display circuit board 12 may be open to the lower surface of the display circuit board 12. The shape of the first opening OP1 may be entirely similar to the shape of the display driving chip 11. According to some embodiments, the first opening OP1 may correspond to a “portion of the opening OP of the display circuit board 12 that is open to the lower surface of the display circuit board 12” described above with reference to FIGS. 2 to 4. When arranging the display circuit board 12 on the display driving chip 11, at least a portion of the display driving chip 11 may be accommodated in the first opening OP1.

The second opening OP2 of the display circuit board 12 may be open to the upper surface of the display circuit board 12. The second opening OP2 may be connected to the first opening OP1 (e.g., spatially). According to some embodiments, the second opening OP2 may correspond to a “portion of the opening OP of the display circuit board 12 that is open to the upper surface of the display circuit board 12” described above with reference to FIGS. 2 to 4. The second opening OP2 may overlap a portion of the display driving chip 11.

According to some embodiments, the opening OP may include a plurality of second openings OP2. In other words, the plurality of second openings OP2 may be defined in the display circuit board 12. The plurality of second openings OP2 may be arranged in one direction (e.g., ±x direction). Although FIG. 5 shows embodiments in which a total of four second openings OP2 are defined in the display circuit board 12, the disclosure is not necessarily limited to this number.

A portion of the display circuit board 12 located between the second openings OP2 adjacent to each other may be understood as the bridge BR. The display circuit board 12 may include the plurality of bridges BR. Similar to the case of the plurality of second openings OP2, the plurality of bridges BR may be arranged in one direction (e.g., ±x direction). Although FIG. 5 shows embodiments in which the display circuit board 12 includes a total of three bridges, the disclosure is not necessarily limited to this number.

Because a portion of the display circuit board 12 located between the second openings OP2 adjacent to each other may be understood as the bridge BR, it may be understood that the plurality of second openings OP2 and the plurality of bridges BR are alternately arranged in one direction (e.g., ±x direction). In addition, it may be understood that the number of the plurality of bridges BR is one less than the number of the plurality of second openings OP2. FIG. 5 shows four second openings OP2 and three bridges BR. As described above, the disclosure is not necessarily limited to this number.

In a plan view, the plurality of second openings OP2 may overlap the first opening OP1 and the display driving chip 11 accommodated in the first opening OP1. Similarly, the plurality of bridges BR may overlap the first opening OP1 and the display driving chip 11 accommodated in the first opening OP1. The plurality of second openings OP2 may expose one surface (e.g., upper surface) of the display driving chip 11, and the plurality of bridges BR may cover one surface (e.g., upper surface) of the display driving chip 11.

Accordingly, it may be understood that the opening OP of the display circuit board 12 is defined by passing through the display circuit board 12 in a region in which the first opening OP1 overlaps the second opening OP2. In other words, it may be understood that the opening OP of the display circuit board 12 is formed as a through hole in the region in which the first opening OP1 overlaps the second opening OP2.

It may be understood that the opening OP of the display circuit board 12 is defined by not passing through the display circuit board 12 in a region in which the first opening OP1 overlaps the bridge BR. In other words, it may be understood that the opening OP of the display circuit board 12 is formed as a blind hole in the region in which the first opening OP1 overlaps the bridge BR.

The display circuit board 12 may include a plurality of wirings LS as electronic elements. The plurality of wirings LS may not be located in a region overlapping the second opening OP2. The plurality of wirings LS may be located on the bridge BR. As an example, the plurality of wirings LS may be located on the plurality of bridges BR. According to some embodiments, some of the plurality of wirings LS extending in a ±y direction may be bent in a region adjacent to the second opening OP2 to detour the second opening OP2. In this case, some of the plurality of wirings LS may be located on the bridge BR. Through this, a larger region for arranging the plurality of wirings LS may be secured than when the first opening OP1 is formed by passing through the display circuit board 12. Through this, the number and density of electronic elements that may be mounted on the display circuit board 12 may be guaranteed. The plurality of wirings LS shown in FIG. 5 are just an example, and all wirings included in the display circuit board 12 do not extend in the ±y direction as shown in FIG. 5.

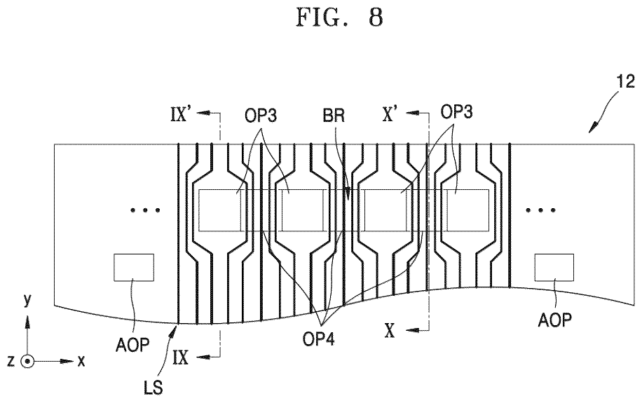

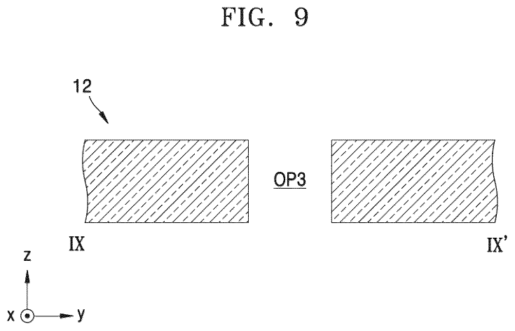

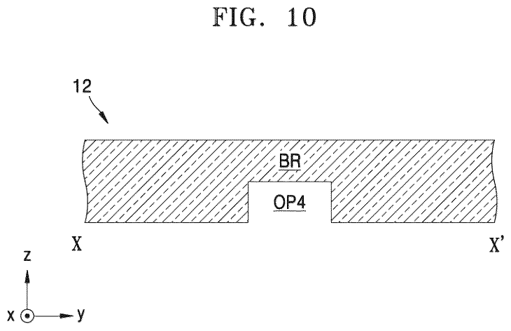

FIG. 8 is a plan view of a portion of the display circuit board 12 according to some embodiments. FIG. 9 is a cross-sectional view of a portion of the display circuit board 12 according to some embodiments. FIG. 10 is a cross-sectional view of a portion of the display circuit board 12 according to some embodiments.

FIG. 9 is a cross-sectional view of the display circuit board 12, taken along line IX-IX′ of FIG. 8. FIG. 10 is a cross-sectional view of the display circuit board 12, taken along line X-X′ of FIG. 8.

Referring to FIGS. 4, 8, 9, and 10 together, the opening OP of the display circuit board 12 may include a third opening OP3 and a fourth opening OP4.

The third opening OP3 of the display circuit board 12 may be defined by passing through the display circuit board 12. In other words, the third opening OP3 may be defined across an entire thickness direction (e.g., ±z direction) of the display circuit board 12. In other words, the third opening OP3 may be formed as a through hole. The third opening OP3 may be open to the upper surface and the lower surface of the display circuit board 12. When arranging the display circuit board 12 on the display driving chip 11, a portion of the display driving chip 11 may fill a portion of the third opening OP3.

The fourth opening OP4 of the display circuit board 12 may be open to the lower surface of the display circuit board 12. The fourth opening OP4 may be defined by not passing through the display circuit board 12. In other words, the fourth opening OP4 may be defined across a portion of the thickness direction (e.g., ±x direction) of the display circuit board 12. In other words, the fourth opening OP4 may be formed as a blind hole that is open to the lower surface of the display circuit board 12. When arranging the display circuit board 12 on the display driving chip 11, a portion of the display driving chip 11 may fill a portion of the fourth opening OP4.

The opening OP of the display circuit board 12 may include a plurality of third openings OP3. The opening OP of the display circuit board 12 may include a plurality of fourth openings OP4. The plurality of third openings OP3 and the plurality of fourth openings OP4 may be alternately arranged in one direction (e.g., ±x direction). As an example, FIG. 8 shows embodiments including four third openings OP3 and three fourth openings OP4. Each of the fourth openings OP4 may be located between the third openings OP3. The disclosure is not limited to a specific number of third openings OP3 or fourth openings OP4.

The plurality of third openings OP3 and the plurality of fourth openings OP4 may be connected (e.g., spatially) to each other. The plurality of third openings OP3 and the plurality of fourth openings OP4 may form a space together in the lower surface of the display circuit board 12, wherein the display driving chip 11 may be accommodated in the space. In other words, the plurality of third openings OP3 and the plurality of fourth openings OP4 may accommodate the display driving chip 11 together.

A portion of the display circuit board 12 located between the third openings OP3 adjacent to each other may be understood as the bridge BR. The display circuit board 12 may include the plurality of bridges BR. Similar to the case of the plurality of third openings OP3 and/or the plurality of fourth openings OP4, the plurality of bridges BR may be arranged in one direction (e.g., ±x direction). Although FIG. 8 shows embodiments in which the display circuit board 12 includes a total of three bridges, the disclosure is not necessarily limited to this number.

Because a portion of the display circuit board 12 located between the third openings OP3 adjacent to each other may be understood as the bridge BR, it may be understood that the plurality of third openings OP3 and the plurality of bridges BR are alternately arranged in one direction (e.g., ±x direction). In addition, it may be understood that the number of the plurality of bridges BR is one less than the number of the plurality of third openings OP3. FIG. 8 shows four third openings OP3 and three bridges BR. As described above, the disclosure is not necessarily limited to this number.

The plurality of bridges BR may overlap the plurality of fourth openings OP4. In other words, the plurality of bridges BR may be located on the plurality of fourth openings OP4. The number of the plurality of bridges BR and the number of plurality of the fourth openings OP4 may be the same.

When the display circuit board 12 is located on the display driving chip 11, the plurality of third openings OP3 may overlap the display driving chip 11. Similarly, the plurality of fourth openings OP4 and the plurality of bridges BR may overlap the display driving chip 11. The plurality of third openings OP3 may expose one surface (e.g., upper surface) of the display driving chip 11, and the plurality of bridges BR may cover one surface (e.g., upper surface) of the display driving chip 11.

The display circuit board 12 may include the plurality of wirings LS as electronic elements. The plurality of wirings LS may not be located in a region overlapping the third opening OP3. The plurality of wirings LS may be located on the bridge BR. As an example, the plurality of wirings LS may be located on the plurality of bridges BR. According to some embodiments, some of the plurality of wirings LS extending in a ±y direction may be bent in a region adjacent to the third opening OP3 to detour the third opening OP3. In this case, some of the plurality of wirings LS may be located on the bridge BR. Accordingly, the plurality of wirings LS may overlap the plurality of fourth openings OP4. Through this, a larger region for arranging the plurality of wirings LS may be secured than when the plurality of bridges BR are not located. Through this, the number and density of electronic elements that may be mounted on the display circuit board 12 may be guaranteed. The plurality of wirings LS shown in FIG. 8 are just an example, and all wirings included in the display circuit board 12 do not extend in the ±y direction as shown in FIG. 8.

FIG. 11A is a cross-sectional view of the display panel 2 according to some embodiments. FIG. 11B is a cross-sectional view of the display panel 2 according to some embodiments.

FIGS. 11A and 11B show embodiments in which the display panel 2 that is bent (e.g., in the bending area BA). FIGS. 11A and 11B may be cross-sectional views of different portions of the same display panel.

Referring to FIGS. 11A and 11B, a portion of the substrate 100 is bent and some of the elements of the display panel 2 may be located under the lower surface of the substrate 100. In this case, the substrate 100 may be bent around the bending axis BAX in the bending area BA.

A portion of the substrate 100 may be located under the lower surface of another portion of the substrate 100. As an example, a second portion 1002 of the substrate 100 corresponding to the second peripheral area PA2 may be located below the lower surface of a first portion 1001 of the substrate 100 corresponding to the first peripheral area PA1 or the display area DA. In this case, a first buffer layer 17 may be located between the first portion 1001 and the second portion 1002 of the substrate 100. The first buffer layer 17 may give strength to the display panel 2 by filling a space between the first portion 1001 and the second portion 1002 of the substrate 100.

In the present disclosure, the upper surface of the first portion 1001 of the substrate 100 may face the +z direction, and the lower surface may face the −z direction. In the case of the second portion 1002 of the substrate 100 positioned below the first portion 1001 of the substrate (100) by bending, the upper surface may face the −z direction and the lower surface may face the +z direction.

The display element layer 200 may overlap the first peripheral area PA1 and the display area DA and be located on the first portion 1001 of the substrate 100.

The display driving chip 11, the display circuit board 12, the plurality of pads 14, and the adhesive layer 16 may overlap the second peripheral area PA2 and be located on the second portion 1002 of the substrate 100. In this case, the display driving chip 11, the display circuit board 12, the plurality of pads 14, and the adhesive layer 16 may be located below the lower surface of the first portion 1001 of the substrate 100. According to some embodiments, the sensor driving chip 13 and the alignment mark 15 (see FIG. 15) may be also located below the lower surface of the first portion 1001 of the substrate 100.

The display driving chip 11 and the plurality of pads 14 may be located on the second portion 1002 of the substrate 100. The display circuit board 12 may be located on the display driving chip 11. The adhesive layer 16 may be located between the display circuit board 12 and the second portion 1002 of the substrate 100. The display circuit board 12 may cover the adhesive layer 16 and the plurality of pads 14 entirely.

A portion of the display circuit board 12 may extend beyond the second portion 1002 of the substrate 100, that is, the second peripheral area PA2. A second buffer layer 18 may be located between a portion of the display circuit board 12 extending beyond the second peripheral area PA2 and the first buffer layer 17. The second buffer layer 18 may provide strength to the display circuit board 12 by preventing or reducing sagging of the display circuit board 12.

Referring to FIG. 11A, the display circuit board 12 may be open to expose a portion of the display driving chip 11. The embodiments shown in FIG. 11A may be a cross-sectional view of a region in which the first opening OP1 overlaps the second opening OP2 in the embodiments described with reference to FIGS. 5 to 7. Alternatively, the embodiments shown in FIG. 11A may be a cross-sectional view of a region corresponding to the third opening OP3 in the embodiments described with reference to FIGS. 8 to 10.

Referring to FIG. 11B, the display circuit board 12 may cover a portion of the display driving chip 11. The embodiments shown in FIG. 11B may be a cross-sectional view of a region in which the first opening OP1 overlaps the bridge BR in the embodiments described with reference to FIGS. 5 to 7. Alternatively, the embodiments shown in FIG. 11B may be a cross-sectional view of a region in which the fourth opening OP4 and the bridge BR are located in the embodiments described with reference to FIGS. 8 to 10.

FIG. 12 is a cross-sectional view of the display panel 2 according to some embodiments.

FIG. 12 show embodiments in which the display panel 2 that is bent (e.g., in the bending area BA).

Because characteristics other than characteristics regarding the shape of the display circuit board 12 in a region overlapping the pad 14 among characteristics of the embodiments shown in FIG. 12 may be the substantially same as characteristics of the embodiments shown in FIG. 11A, repeated descriptions are omitted. In addition, the characteristics described with reference to FIG. 12 may be combined with the embodiments shown in FIG. 11B.

Referring to FIG. 12, the display circuit board 12 may be pressed onto the substrate 100 in a region overlapping the pad 14. Accordingly, the thickness of the display circuit board 12 in the region overlapping the pad 14 may be less than the thickness of the display circuit board 12 in the other regions. To express this, it is shown in FIG. 12 that the display circuit board 12 is open in the region overlapping the pad 14. In this case, a portion of the pad 14 may be exposed as shown in FIG. 12. As an example, the lateral surface of the pad 14 may be covered by the display circuit board 12, and the upper surface of the pad 14 may be exposed. According to some embodiments, the exposed upper surface of the pad 14 may be connected to another electronic element. This is just an example, and only the thickness of the display circuit board 12 changes due to pressing, and the pad 14 may be still covered by the display circuit board 12.

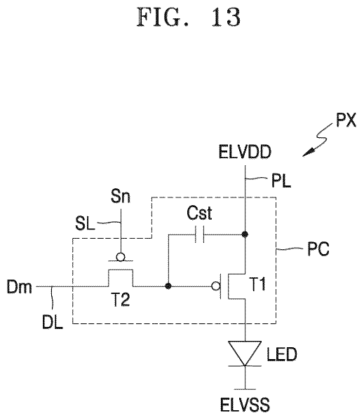

FIG. 13 is a schematic circuit diagram of a light-emitting diode LED and a pixel circuit PC connected to the light-emitting diode LED provided to a pixel PX according to some embodiments. Although FIG. 13 illustrates various components in a pixel circuit according to some embodiments, embodiments according to the present disclosure are not limited thereto, and according to various embodiments, the pixel circuit may include additional components without departing from the spirit and scope of embodiments according to the present disclosure.

Referring to FIG. 13, the pixel circuit PC may be connected to the light-emitting diode LED to implement light emission of pixels PX. The pixel circuit PC may include a first transistor T1, a second transistor T2, and a storage capacitor Cst. According to some embodiments, the first transistor T1 may be a driving transistor, and the second transistor T2 may be a switching transistor. The second transistor T2 may be connected to a scan line SL and a data line DL, and configured to transfer a data signal Dm to the first transistor T1 according to a scan signal Sn, wherein the data signal Dm is input through the data line DL, and the scan signal Sn is input through the scan line SL.

The storage capacitor Cst may be connected to the second transistor T2 and a driving voltage line PL and configured to store a voltage corresponding to a difference between a voltage transferred from the second transistor T2 and a driving voltage ELVDD supplied to the driving voltage line PL.

The first transistor T1 may be connected to the driving voltage line PL and the storage capacitor Cst and configured to control a driving current according to the voltage stored in the storage capacitor Cst, the driving current flowing from the driving voltage line PL to the light-emitting diode LED. The light-emitting diode LED may receive a common voltage ELVSS and be configured to emit light having a preset brightness corresponding to the driving current.

The pixel circuit PC is not limited to the number of thin-film transistors, the number of storage capacitors, and the circuit design described with reference to FIG. 13, and the number of thin-film transistors, the number of storage capacitors, and the circuit design may be variously changed.

FIG. 14 is a cross-sectional view of the display panel 2 according to some embodiments. FIG. 14 may be a cross-sectional view of the display panel 2, taken along line II-II′ of FIG. 2.

Referring to FIG. 14, the display element layer 200 of the display panel 2 may include, for example, the light-emitting diode LED as a light-emitting element. However, the disclosure is not necessarily limited thereto, and the display panel 2 may include other light-emitting apparatuses such as a liquid crystal display and electrophoretic display as a light-emitting element.

A buffer layer 201 may be located on the substrate 100. The buffer layer 201 may include an inorganic material such as silicon oxide (SiO₂), silicon nitride (SiN_{X}), and/or silicon oxynitride (SiON). The buffer layer 201 may increase a smoothness of the upper surface of the substrate 100 or prevent or reduce impurities or contaminants penetrating an active layer 202 of a thin-film transistor TFT. According to some embodiments, the buffer layer 201 may be omitted.

The thin-film transistor TFT may be arranged over the substrate 100. The thin-film transistor TFT may be electrically connected to a pixel electrode 209. The thin-film transistor TFT may include an active layer 202, a gate electrode 204, a source electrode 2061, and a drain electrode 2062. The active layer 202 may include a semiconductor material such as amorphous silicon, polycrystalline silicon, an oxide semiconductor material or an organic semiconductor. The gate electrode 204 may be insulated from the active layer 202. Each of the source electrode 2061 and the drain electrode 2062 may be electrically connected to the active layer 202. The gate electrode 204 may be arranged over the active layer 202, and the source electrode 2061 and the drain electrode 2062 may electrically communicate with each other according to a signal applied to the gate electrode 204. The gate electrode 204 may include at least one of aluminum (Al), platinum (Pt), palladium (Pd), silver (Ag), magnesium (Mg), gold (Au), nickel (Ni), neodymium (Nd), iridium (Ir), chrome (Cr), lithium (Li), calcium (Ca), molybdenum (Mo), titanium (Ti), tungsten (W), or copper (Cu), and include a single layer or a multi-layer by taking into account adhesion with adjacent layers, surface flatness of stacked layers, workability, and the like.

For insulation between the active layer 202 and the gate electrode 204, a first insulating layer 203 may be located between the active layer 202 and the gate electrode 204. The first insulating layer 203 may include an inorganic material such as silicon oxide (SiO₂), silicon nitride (SiN_{X}), and/or silicon oxynitride (SiON). According to some embodiments, the first insulating layer 203 may be patterned to correspond to the shape of the gate electrode 204. A second insulating layer 205 may be located on the gate electrode 204, and the source electrode 2061 and the drain electrode 2062 may be located on the second insulating layer 205. The source electrode 2061 and the drain electrode 2062 may be respectively electrically connected to the active layer 202 through contact holes formed in the first insulating layer 203. The second insulating layer 205 may include an inorganic material such as silicon oxide (SiO₂), silicon nitride (SiN_{X}), and/or silicon oxynitride (SiON).

A third insulating layer 207 may be located on the thin-film transistor TFT, wherein the third insulating layer 207 covers the thin-film transistor TFT. The third insulating layer 207 may have a flat upper surface such that the pixel electrode 209 is formed flat. The third insulating layer 207 may include an organic material such as acryl, benzocyclobutene (BCB), polyimide (PI), or hexamethyldisiloxane (HMDSO). Although it is shown in FIG. 14 that the third insulating layer 207 is a single layer, the third insulating layer 207 may have a multi-layered structure.

The third insulating layer 207 may include a via hole exposing one of the source electrode 2061 and the drain electrode 2062 of the thin-film transistor TFT. The pixel electrode 209 may be electrically connected to the thin-film transistor TFT by being in contact with one of the source electrode 2061 and the drain electrode 2062 through the via hole. As an example, it is shown in FIG. 14 that the pixel electrode 209 is connected to the drain electrode 2062.

The light-emitting diode LED may be located on the third insulating layer 207, wherein the light-emitting diode LED includes the pixel electrode 209, an intermediate layer 210 located on the pixel electrode 209 and including an emission layer, and an opposite electrode 211.

According to some embodiments, the pixel electrode 209 may include a reflective electrode. In the case where the pixel electrode 209 includes a reflective electrode, the pixel electrode 209 may include a reflective layer and a transparent conductive layer located on and/or under the reflective layer, the reflective layer including silver (Ag), magnesium (Mg), aluminum (Al), platinum (Pt), palladium (Pd), gold (Au), nickel (Ni), neodymium (Nd), iridium (Ir), chrome (Cr), or a compound thereof. The transparent conductive layer may include at least one selected from among indium tin oxide (ITO), indium zinc oxide (IZO), zinc oxide (ZnO), indium oxide (In₂O₃), indium gallium oxide (IGO), and aluminum-zinc oxide (AZO). However, the disclosure is not limited thereto and the pixel electrode 209 may include various materials, and the structure thereof may be a single-layered structure or a multi-layered structure and be variously modified.

A pixel-defining layer 208 may be located on the third insulating layer 207, wherein the pixel-defining layer 208 covers edge regions of the pixel electrode 209. The pixel-defining layer 208 may have an opening exposing at least a portion of the pixel electrode 209 and define an emission area EA of the light-emitting diode LED. The pixel-defining layer 208 may include an organic material such as polyimide (PI) or hexamethyldisiloxane (HMDSO). The pixel-defining layer 208 may include a single layer or a multi-layer.

The intermediate layer 210 may be located on the central portion of the pixel electrode 209 exposed by the pixel-defining layer 208. The intermediate layer 210 may include an emission layer (EML), and in addition, may further include functional layers such as a hole injection layer (HIL), a hole transport layer (HTL), an electron transport layer (ETL), and/or an electron injection layer (EIL).

The structure of the intermediate layer 210 is not necessarily limited thereto and may have various structures. In addition, the intermediate layer 210 may include an integral layer over a plurality of pixel electrodes 209, or include a layer patterned to correspond to each of the plurality of pixel electrodes 209.

The opposite electrode 211 may be located on the intermediate layer 210. Unlike the pixel electrode 209, the opposite electrode 211 may be integrally formed over the plurality of pixels.

The opposite electrode 211 may include a transparent or semi-transparent electrode. In the case where the opposite electrode 211 includes a transparent or semi-transparent electrode, the opposite electrode 88 may include a thin-film including at least one selected from among silver (Ag), aluminum (Al), magnesium (Mg), lithium (Li), calcium (Ca), copper (Cu), lithium/calcium fluoride (LiF/Ca), lithium/aluminum fluoride (LiF/Al), magnesium-silver alloy (MgAg), and calcium-silver alloy (CaAg). The construction and material of the opposite electrode 211 are not limited thereto and may be variously modified.

A thin-film encapsulation layer TFE may be located on the opposite electrode 211. The thin-film encapsulation layer TFE may seal the light-emitting diode LED such that the light-emitting diode LED is not exposed to external air or foreign substance. The thin-film encapsulation layer TFE has a thin thickness and may be used as a sealing means of a flexible display apparatus that is bendable or foldable.

The thin-film encapsulation layer TFE may include a first inorganic encapsulation layer 212, an organic encapsulation layer 213, and a second inorganic encapsulation layer 214 sequentially located on the opposite electrode 211. The first inorganic encapsulation layer 212 may include silicon oxide (SiO₂), silicon nitride (SiN_{X}), and/or silicon oxynitride (SiON). Because the first inorganic encapsulation layer 212 is formed along a structure thereunder, an upper surface thereof may not be flat. The organic encapsulation layer 213 covers the first inorganic encapsulation layer 212 and may form a flat upper surface. The organic encapsulation layer 213 may include at least one material selected from among polyethylene terephthalate, polyethylene naphthalate, polycarbonate, polyimide, polyethylene sulfonate, polyoxymethylene, and polyarylate, hexamethyldisiloxane. The second inorganic encapsulation layer 214 may cover the organic encapsulation layer 213 and may include silicon oxide (SiO₂), silicon nitride (SiNₓ), and/or silicon oxynitride (SiON). Although it is shown as an example in FIG. 14 that the thin-film encapsulation layer TFE includes one organic encapsulation layer 213, the thin-film encapsulation layer TFE may have a structure in which a plurality of organic encapsulation layers and inorganic encapsulation layers are alternately stacked.

According to some embodiments, stability of connection between the display circuit board and the substrate (particularly during a processing operation) may be secured by allowing the display circuit board to partially overlap the substrate.

According to some embodiments, because the opening that overlaps the display driving chip and is open to the upper surface of the display circuit board is provided in the display circuit board, a path through which heat occurring from the display driving chip may be discharged may be secured, and thus, overheating of the display driving chip may be prevented or reduced.

According to some embodiments, because, when forming the opening in the display circuit board, the display circuit board is not removed in a region overlapping the display driving chip and a portion of the display circuit board is left in the form of the bridge, a space on which an electronic element (e.g., a wiring) of the display circuit board may be located may be secured.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, and their equivalents.

What is claimed is:

1. A display panel comprising:
a substrate including a display area and a peripheral area outside the display area;
a plurality of display elements on the substrate in the display area;
a display driving chip on the substrate in the peripheral area; and
a display circuit board on the display driving chip,
wherein the display circuit board includes:
a first opening defined in a lower surface of the display circuit board to accommodate the display driving chip; and
a bridge on the first opening and partially covering an upper surface of the display driving chip.

2. The display panel of claim 1, wherein the display circuit board includes a second opening connected to the first opening and open to an upper surface of the display circuit board.

3. The display panel of claim 2, wherein the display circuit board includes a plurality of second openings and a plurality of bridges, and the plurality of second openings and the plurality of bridges are alternately arranged in one direction.

4. The display panel of claim 1, wherein the display circuit board includes a plurality of wirings on the bridge.

5. The display panel of claim 1, further comprising a plurality of pads on the substrate; and an alignment mark adjacent to an outermost pad among the plurality of pads, wherein the display circuit board includes an alignment opening overlapping the alignment mark.

6. The display panel of claim 1, further comprising an adhesive layer between the substrate and the display circuit board, wherein the adhesive layer includes an opening overlapping the display driving chip.

7. The display panel of claim 1, wherein the substrate is bent in the peripheral area, and the display driving chip and the display circuit board are below one surface of the substrate.

8. An electronic apparatus including a display panel and a housing accommodating the display panel,
wherein the display panel includes:
a substrate including a display area and a peripheral area outside the display area;
a plurality of display elements on the substrate in the display area;
a display driving chip on the substrate in the peripheral area; and
a display circuit board on the display driving chip,
wherein the display circuit board includes:
a plurality of first openings overlapping the display driving chip and defined across an entire thickness direction of the display circuit board; and
a plurality of second openings overlapping the display driving chip and defined across a portion of the thickness direction of the display circuit board, and
wherein the plurality of first openings and the plurality of second openings are alternately arranged in one direction.

9. The electronic apparatus of claim 8, wherein the plurality of first openings and the plurality of second openings are connected to each other.

10. The electronic apparatus of claim 9, wherein the plurality of second openings are open to a lower surface of the display circuit board.

11. The electronic apparatus of claim 10, wherein the plurality of first openings and the plurality of second openings are configured to accommodate the display driving chip.

12. The electronic apparatus of claim 8, wherein the display circuit board includes a plurality of wirings at least partially overlapping the plurality of second openings.

13. The electronic apparatus of claim 8, further comprising a plurality of pads on the substrate; and an alignment mark adjacent to an outermost pad among the plurality of pads, wherein the display circuit board includes an alignment opening overlapping the alignment mark.

14. The electronic apparatus of claim 8, further comprising an adhesive layer between the substrate and the display circuit board, wherein the adhesive layer includes an opening overlapping the display driving chip.

15. The electronic apparatus of claim 8, wherein the substrate is bent in the peripheral area, and the display driving chip and the display circuit board are located below one surface of the substrate.

16. An electronic apparatus including a display panel and a housing accommodating the display panel,
wherein the display panel includes:
a substrate including a display area and a peripheral area outside the display area;
a plurality of display elements on the substrate in the display area;
a display driving chip on the substrate in the peripheral area; and
a display circuit board on the display driving chip, and
wherein the display circuit board includes:
a first opening defined in a lower surface of the display circuit board to accommodate the display driving chip; and
a bridge on the first opening and partially covering an upper surface of the display driving chip.

17. The electronic apparatus of claim 16, wherein the display circuit board includes a second opening connected to the first opening and open to an upper surface of the display circuit board.

18. The electronic apparatus of claim 17, wherein the display circuit board includes a plurality of second openings and a plurality of bridges, and the plurality of second openings and the plurality of bridges are alternately arranged in one direction.

19. The electronic apparatus of claim 16, wherein the display circuit board includes a plurality of wirings on the bridge.
